(19) United States
(12) Patent Application Publication
(10) Pub. No.: US 2012/0196449 A1
(43) Pub. Date: Aug. 2, 2012

(54) ZIRCONIUM, HAFNIUM AND TITANIUM PRECURSORS FOR ATOMIC LAYER DEPOSITION OF CORRESPONDING METAL-CONTAINING FILMS

(75) Inventors: Chongying Xu, New Milford, CT (US); Thomas M. Cameron, Newtown, CT (US); William Hunks, Waterbury, CT (US)

(73) Assignee: ADVANCED TECHNOLOGY MATERIALS, INC., Danbury, CT (US)

(21) Appl. No.: 13/360,453

(22) Filed: Jan. 27, 2012

Related U.S. Application Data
(60) Provisional application No. 61/437,002, filed on Jan. 27, 2011.

(51) Int. Cl. C07F 17/00; H01L 21/02; C23C 16/40; C07F 7/00; C23C 16/06; C07F 7/28

(52) U.S. Cl. 438/785; 427/126.3; 556/52; 556/53; 106/287.19; 257/E21.008

(57) ABSTRACT

A zirconium precursor selected from among compounds of Formulae (I), (II) and (III):

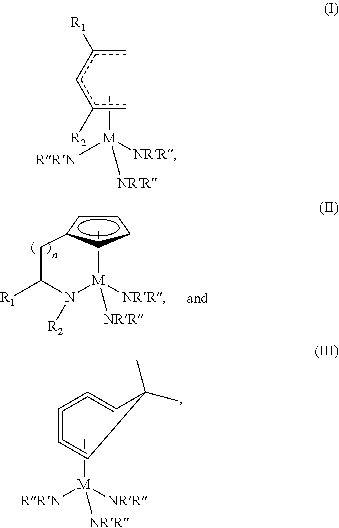

wherein: M is Zr, Hf or Ti; R₁ is hydrogen or C₁-C₅ alkyl; each of R₂, R′ and R″ is independently selected from C₁-C₅ alkyl; and n has a value of 0, 1, 2, 3 or 4. Compounds of such formulae are useful in vapor deposition processes such as atomic layer deposition, to form corresponding metal-containing films, e.g., high k dielectric zirconium films in the fabrication of DRAM memory cells.

### CROSS-REFERENCE TO RELATED APPLICATION

The benefit of priority under 35 USC 119 of U.S. Provisional Patent Application 61/437,002 filed Jan. 27, 2011 in the names of Chongying Xu for “Zirconium, Hafnium and Titanium Precursors for Atomic Layer Deposition of Corresponding Metal-Containing Films” is hereby claimed. The disclosure of such U.S. Provisional Patent Application 61/437,002 is hereby incorporated herein by reference, for all purposes.

### FIELD OF THE DISCLOSURE

The present disclosure relates to zirconium, hafnium, and titanium precursors useful in vapor deposition processes, e.g., atomic layer deposition (ALD), to form a corresponding metal oxide films on substrates, as well as methods of making and using such precursors and films, e.g., in the manufacture of microelectronic devices or device precursor structures, e.g., dielectric material structures, such as ferroelectric capacitors, dynamic random access memory devices, and the like.

### DESCRIPTION OF THE RELATED ART

Zirconium-containing materials, e.g., zirconium oxide (ZrO₂), are currently contemplated for extensive use in high dielectric constant (k) dielectric films in the manufacture of next-generation semiconductor devices and microelectronic products, e.g., in DRAM capacitors employing ZrO₂ based dielectrics and ferroelectrics. Zirconium oxide is a very good candidate for the 4× nm technology node due to its high dielectric constant (˜40) and high bandgap (˜5.7 eV). Such films can be formed by use of appropriate zirconium precursors, in vapor deposition processes, such as chemical vapor deposition (CVD) and atomic layer deposition (ALD).

In these vapor deposition operations, the zirconium precursor, typically an organozirconium compound in solid or liquid form, is volatilized to form a corresponding precursor vapor. The resulting precursor vapor is transported to a vapor deposition chamber, in which the precursor vapor is contacted with a substrate, such as a semiconductor wafer, to deposit the metal on the substrate.

For such usage, the metal precursor must have appropriate thermal stability. Many existing zirconium precursors lack the thermal stability required for CVD and ALD processing, and suffer premature decomposition and degrade to form undesired byproducts. These undesired byproducts include solid byproducts that can clog vapor flow passages and delivery equipment and particles and impurities that can render the wafer being processed grossly deficient or even useless for its intended purpose. Specifically, many organozirconium precursors lack thermal stability for ALD processes at the high temperatures required to achieve desired device performance.

The art therefore is in search of new organozirconium precursors having superior stability, good volatilization and transport properties, and compatibility with the process conditions of vapor deposition processes such as CVD and ALD.

Similar considerations inform the ongoing search for new and improved organometallic precursors, such as organotitanium and organohafnium precursors.

### SUMMARY

The present disclosure relates to zirconium, hafnium, and titanium precursors, and corresponding zirconium-containing films, hafnium-containing films, and titanium-containing films, respectively, and to methods of making and using such precursors and films.

In one aspect, the disclosure relates to a precursor selected from the group consisting of compounds of Formulae (I), (II) and (III):

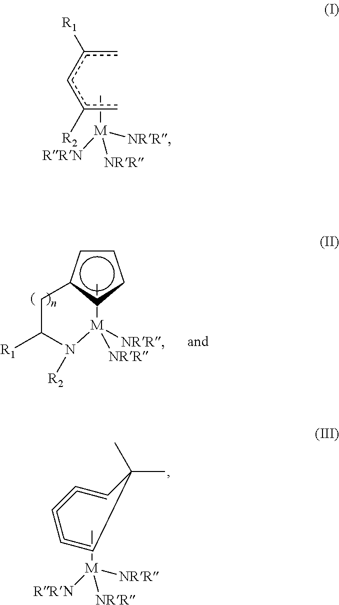

wherein:

### M is Zr, Hf or Ti;

R₁ is hydrogen or C₁-C₅ alkyl;
each of R₂, R′ and R″ is independently selected from C₁-C₅ alkyl; and
n has a value of 0, 1, 2, 3 or 4.

In another aspect, the disclosure relates to a zirconium precursor selected from the group consisting of compounds of Formulae (I), (II), and (III):

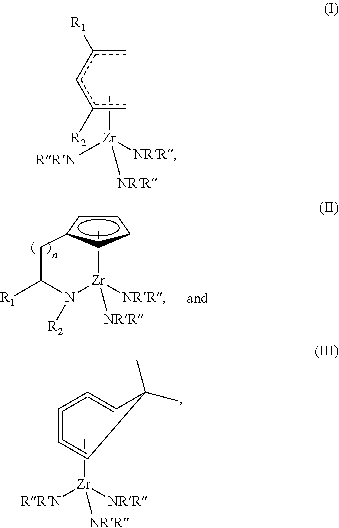

wherein:
R₁ is hydrogen or C₁-C₅ alkyl;
each of R₂, R′ and R″ is independently selected from C₁-C₅ alkyl; and
n has a value of 0, 1, 2, 3 or 4.

In another aspect, the disclosure relates to a hafnium precursor selected from the group consisting of compounds of Formulae (I), (II), and (III):

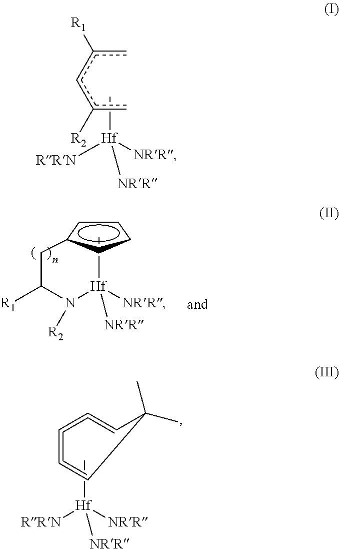

wherein:
R₁ is hydrogen or C₁-C₅ alkyl;
each of R₂, R′ and R″ is independently selected from C₁-C₅ alkyl; and
n has a value of 0, 1, 2, 3 or 4.

A still further aspect of the disclosure relates to a titanium precursor selected from the group consisting of compounds of Formulae (I), (II), and (III):

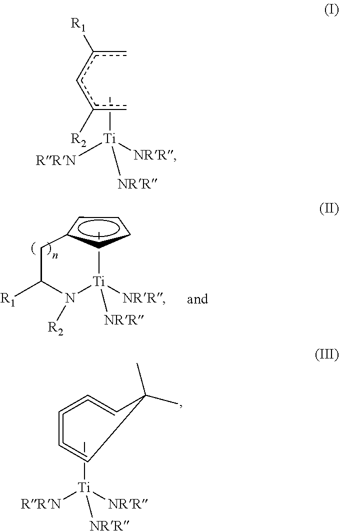

wherein:
R₁ is hydrogen or C₁-C₅ alkyl;
each of R₂, R′ and R″ is independently selected from C₁-C₅ alkyl; and
n has a value of 0, 1, 2, 3 or 4.

A further aspect of the disclosure relates to a zirconium precursor of Formula (I).

A still further aspect of the disclosure relates to a zirconium precursor of Formula (II).

Yet another aspect of the disclosure relates to a zirconium precursor of Formula (III).

Another aspect of the disclosure relates to a hafnium precursor of Formula (I).

In another aspect, the disclosure relates to a hafnium precursor of Formula (II).

Another aspect of the disclosure relates to a hafnium precursor of Formula (III).

A further aspect of the disclosure relates to a titanium precursor of Formula (I).

A still further aspect of the disclosure relates to a titanium precursor of Formula (II).

Yet another aspect of the disclosure relates to a titanium precursor of Formula (III).

In a still further aspect, the disclosure relates to a precursor composition comprising a precursor as described above and a solvent medium therefor.

A further aspect of the invention relates to a method of forming a film on a substrate, comprising conducting a vapor deposition process using a precursor of the disclosure as a metal source compound for such vapor deposition process.

A still further aspect of the invention relates to a vessel containing a precursor of the disclosure.

In yet another aspect, the disclosure relates to a composition comprising a precursor compound of the disclosure and a vapor deposition stabilization additive, e.g., a stabilizer selected from the group consisting of: alkylamines; free radical inhibitors; and compounds that maintain the precursor metal in the +4 oxidation state.

Other aspects, features and embodiments of the invention will be more fully apparent from the ensuing disclosure and appended claims.

### BRIEF DESCRIPTION OF THE DRAWINGS

FIG. 1 is a schematic representation of a microelectronic device including a zirconium dioxide-based dielectric material and top and bottom electrodes.

FIG. 2 is a schematic representation of a material storage and dispensing package containing a precursor of the present invention, in one embodiment thereof.

### DETAILED DESCRIPTION

The present disclosure relates to zirconium, hafnium, and titanium precursors and corresponding zirconium-containing films, hafnium-containing films, and titanium-containing films, respectively, and to methods of making and using such precursors and films.

As used herein, the term “film” refers to a layer of deposited material having a thickness below 1000 micrometers, e.g., from such value down to atomic monolayer thickness values. In various embodiments, film thicknesses of deposited material layers in the practice of the disclosure may for example be below 100, 10, or 1 micrometers, or in various thin film regimes below 200, 100, or 50 nanometers, depending on the specific application involved. As used herein, the term “thin film” means a layer of a material having a thickness below 1 micrometer.

As used herein, the singular forms “a”, “and”, and “the” include plural referents unless the context clearly dictates otherwise.

As used herein, the identification of a carbon number range, e.g., in C₁-C₁₂ alkyl, is intended to include each of the component carbon number moieties within such range, so that each intervening carbon number and any other stated or intervening carbon number value in that stated range, is encompassed, it being further understood that sub-ranges of carbon number within specified carbon number ranges may independently be included in smaller carbon number ranges, within the scope of the invention, and that ranges of carbon numbers specifically excluding a carbon number or numbers are included in the invention, and sub-ranges excluding either or both of carbon number limits of specified ranges are also included in the disclosure.

Accordingly, C₁-C₁₂ alkyl is intended to include methyl, ethyl, propyl, butyl, pentyl, hexyl, heptyl, octyl, nonyl, decyl, undecyl and dodecyl, including straight chain as well as branched groups of such types. It therefore is to be appreciated that identification of a carbon number range, e.g., C₁-C₁₂, as broadly applicable to a substituent moiety, enables, in specific embodiments of the disclosure, the carbon number range to be further restricted, as a sub-group of moieties having a carbon number range within the broader specification of the substituent moiety. By way of example, the carbon number range e.g., C₁-C₁₂ alkyl, may be more restrictively specified, in particular embodiments of the disclosure, to encompass sub-ranges such as C₁-C₄ alkyl, C₂-C₈ alkyl, C₂-C₄ alkyl, C₃-C₅ alkyl, or any other sub-range within the broad carbon number range. Thus, for example, the range C₁-C₆ would be inclusive of and can be further limited by specification of sub-ranges such as C₁-C₃, C₂-C₆, C₄-C₆, etc. within the scope of the broader range.

The precursors of the disclosure may be further specified in specific embodiments by provisos or limitations excluding specific substituents, groups, moieties or structures, in relation to various specifications and exemplifications thereof set forth herein. Thus, the disclosure contemplates restrictively defined compositions, e.g., a composition wherein R is C₁-C₁₂ alkyl, with the proviso that R≠Cᵢ alkyl when M or X is a specified molecular component, and i is a specific carbon number.

The disclosure, as variously set out herein in respect of various described features, aspects and embodiments, may in particular implementations be constituted as comprising, consisting, or consisting essentially of, some or all of such features, aspects and embodiments, as well as elements and components thereof being aggregated to constitute various further implementations of the disclosure. The disclosure contemplates such features, aspects and embodiments in various permutations and combinations, as being within the scope of the disclosure. The disclosure may therefore be specified as comprising, consisting or consisting essentially of, any of such combinations and permutations of these specific features, aspects and embodiments, or a selected one or ones thereof.

The precursors of the disclosure have particular utility in the manufacture of microelectronic devices and microelectronic device precursor structures. For example, zirconium precursors of the disclosure may be utilized to manufacture high κ dielectric material structures, such as ferroelectric capacitors, dynamic random access memory devices, and the like. The precursors of the disclosure are particularly useful in atomic layer deposition (ALD) in the manufacture of microelectronic devices or microelectronic device precursor structures, due to the high volatility, superior thermal stability, and high surface reactivity on wafer surfaces exhibited by such precursors.

The precursors of the disclosure are readily synthesized, as discussed more fully hereinafter.

In application to ALD and other vapor deposition processes, precursors of the disclosure can be delivered at low temperature, e.g., 90-150° C., with a liquid bubbler, and are thermally stable at such delivery temperatures, i.e., do not thermally decompose. These precursors can be used in ALD as well as other vapor deposition processes, and such vapor deposition processes may for example be carried out at temperature of 200-300° C. The precursor can be delivered, by bubbling an appropriate carrier gas through the precursor liquid, to entrain vapor associated with the liquid by virtue of its vapor pressure, in the carrier gas.

In various embodiments, precursors of the present disclosure can be employed in formulations that include one or more additives that are effective to enhance the thermal stability of the precursor. Suitable additives can include
(i) alkylamines, such as ethylmethylamine, isopropylmethylamine, diethylamine, trimethylamine, n-propylmethylamine, t-butylamine, triethylamine, etc.;
(ii) free radical inhibitors; and
(iii) compounds that maintain Zr in the +4 oxidation state, such as hydrazino compounds, e.g., dimethyl hydrazine.

In specific embodiments, amounts of the thermal stabilization additive on the order of 0.1 to 5% by weight, based on weight of precursor in the formulation, can be usefully employed, with amounts of the thermal stabilization additive on the order of 0.5 to 2.5% by weight, on the same weight basis, being preferred.

In various embodiments, formulations including the zirconium precursors disclosed herein, and additional ingredients, such as one or more additives of the types discussed above, are particularly usefully employed in the deposition of zirconium-containing films, e.g., high k zirconia dielectric materials for the fabrication of power-on-reset (POR) circuitry in memory chip applications such as DRAM capacitors.

Formulations of the precursors of the present disclosure can be used in vapor deposition applications, such as atomic layer deposition (ALD) and chemical vapor deposition (CVD), utilizing appropriate oxidizers, co-reactants, process conditions, etc., within the skill of the art, based on the disclosure herein. The vapor deposition process may involve direct liquid injection (DLI) and bubbler techniques in delivery of the precursor. Useful oxidizers in specific embodiments can include ozone, water, oxygen, peroxides, nitrous oxide, carbon dioxide and/or alcohols.

It will be recognized that multiple additives can be employed in specific embodiments of the disclosure, to constitute formulations that achieve enhanced thermal stability of the precursor, and improved step coverage on high aspect ratio structures, in relation to corresponding formulations lacking such additives. Multiple additive formulations of such type can be determined as to the relative proportions of the precursor and additive(s) appropriate to a given implementation of the invention, by empirical determination involving varying concentrations of the respective components of the formulation to determine resulting stability and step coverage characteristics.

Vapor deposition processes using the precursors of the invention can be carried out under any suitable process conditions (temperatures, pressures, flow rates, concentrations, ambient environment, etc.) that are appropriate to form corresponding metal-containing films of a desired character, within the skill of the art, and based on the disclosure herein.

In an ALD process embodiment, precursor vapor is introduced to a vapor deposition chamber, following which a purge gas is pulsed to the chamber to remove such precursor gas mixture. Next, a second fluid is introduced to the vapor deposition chamber to complete the reaction sequence. The second fluid may for example comprise oxygen for the formation of an oxide film on the substrate, such as a ZrO₂, HfO₂, or TiO₂ film. Alternatively, the second fluid may comprise nitrogen, for formation of a nitride film on the substrate, or the second fluid may comprise sulfur, for formation of a sulfide film on the substrate.

In various embodiments, precursors of the present disclosure, e.g., zirconium precursors, can be used to manufacture high κ dielectric material structures, such as ferroelectric capacitors or dynamic random access memory devices (DRAMs) comprising high κ dielectric capacitors or as gate dielectric material structures in logic devices.

Metal films formed from metal precursors of the present disclosure can be doped, co-deposited, alloyed or layered with a secondary material, e.g., a material (different from the primary metal of the film) selected from among Nb, Ta, Ti, Zr, Hf, Ge, Si, Sn, La, Y, Ce, Pr, Nd, Gd, Dy, Sr, Ba, Ca, and Mg, and oxides of such metals, wherein Al₂O₃, when present, is a dopant or alloying secondary material. For example, various embodiments of the disclosure contemplate zirconium-containing films being formed from precursors of the disclosure, in which the zirconium-containing film is optionally doped with a dopant material, e.g., a Group IV dopant species.

ALD formation of conformal thin films of metal (Zr, Hf, or Ti) oxide can be formed using precursors of the present disclosure, at temperature in a range of from 200° C. to 350° C., using oxygen sources such as oxygen, ozone, water, peroxides, nitrous oxide, carbon dioxide, carbon dioxide or alcohols, at pressure of from 0.2 to 20 Torr. The oxidizers can be activated by remote or direct plasma. CVD oxides can use the same oxygen sources (excepting ozone, peroxide, and plasma activation), and the CVD process can be carried out at temperature of from 200° C. to 600° C. and pressure in a range of from 0.2 to 10.0 Torr, but higher temperature and pressure conditions will require lower oxidizer concentrations to avoid gas-phase reactions.

The metal (Zr, Hf, or Ti) precursors disclosed herein are readily synthesized, by reaction of a corresponding amine or amide, e.g., a germanium or silicon amide, with butyl lithium in an alkane or ether solvent, e.g., hexane, and reaction with metal (Zr, Hf, or Ti) chloride, followed by filtration, solvent stripping and vacuum distillation to recover the metal precursor product.

The metal precursors of the invention can be used in ALD, CVD or other vapor deposition processes to deposit metal films on substrates, e.g., (Zr, Hf, or Ti) dioxide films, PZT films, PLZT films, (Zr, Hf, or Ti) nitride films, etc.

In one aspect, the disclosure relates to a precursor selected from the group consisting of compounds of Formulae (I), (II) and (III):

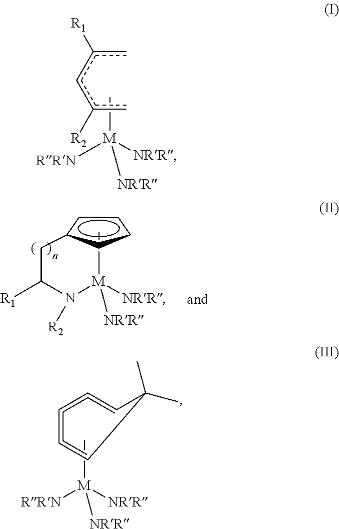

wherein:

### M is Zr, Hf or Ti;

R₁ is hydrogen or C₁-C₅ alkyl;
each of R₂, R′ and R″ is independently selected from C₁-C₅ alkyl; and
n has a value of 0, 1, 2, 3 or 4.

A further aspect of the disclosure relates to a zirconium precursor of Formula (I).

A still further aspect of the disclosure relates to a zirconium precursor of Formula (II).

Yet another aspect of the disclosure relates to a zirconium precursor of Formula

Another aspect of the disclosure relates to a hafnium precursor of Formula (I).

In another aspect, the disclosure relates to a hafnium precursor of Formula (II).

Another aspect of the disclosure relates to a hafnium precursor of Formula (III).

A further aspect of the disclosure relates to a titanium precursor of Formula (I).

A still further aspect of the disclosure relates to a titanium precursor of Formula (II).

Yet another aspect of the disclosure relates to a titanium precursor of Formula (III).

In another aspect, the disclosure relates to a zirconium precursor selected from the group consisting of compounds of Formulae (I), (II), and (III):

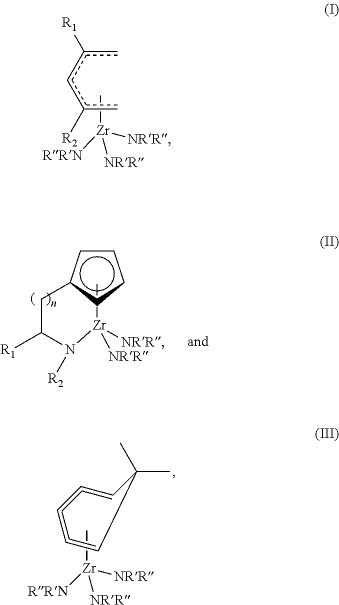

wherein:
R₁ is hydrogen or C₁-C₅ alkyl;
each of R₂, R′ and R″ is independently selected from C₁-C₅ alkyl; and
n has a value of 0, 1, 2, 3 or 4.

In another aspect, the disclosure relates to a hafnium precursor selected from the group consisting of compounds of Formulae (I), (II), and (III):

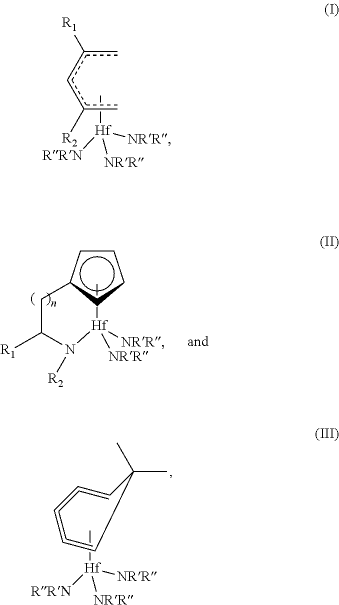

wherein:
R₁ is hydrogen or C₁-C₅ alkyl;
each of R₂, R′ and R″ is independently selected from C₁-C₅ alkyl; and
n has a value of 0, 1, 2, 3 or 4.

A still further aspect of the disclosure relates to a titanium precursor selected from the group consisting of compounds of Formulae (I), (II), and (III):

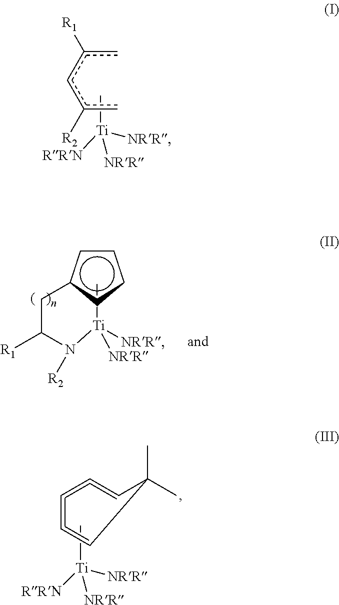

wherein:
R₁ is hydrogen or C₁-C₅ alkyl;
each of R₂, R′ and R″ is independently selected from C₁-C₅ alkyl; and
n has a value of 0, 1, 2, 3 or 4.

In a still further aspect, the disclosure relates to a precursor composition comprising a precursor as described above and a solvent medium therefor.

A further aspect of the invention relates to a method of forming a film on a substrate, comprising conducting a vapor deposition process using a precursor of the disclosure as a metal source compound for such vapor deposition process.

A still further aspect of the invention relates to a vessel containing a precursor of the disclosure.

In yet another aspect, the disclosure relates to a composition comprising a precursor compound of the disclosure and a vapor deposition stabilization additive, e.g., a stabilizer selected from the group consisting of: alkylamines; free radical inhibitors; and compounds that maintain the precursor metal in the +4 oxidation state.

In various preferred embodiments of the disclosure, the metal precursor comprises a zirconium compound of Formula (I). In some specific embodiments of such zirconium compounds, R₁ is hydrogen. In other specific embodiments, R₁ in the zirconium compound is C₁-C₅ alkyl.

In various other preferred embodiments of the disclosure, the metal precursor comprises a zirconium compound of Formula (II). In some specific embodiments of such zirconium compounds, R₁ is hydrogen. In other specific embodiments, R₁ in the zirconium compound is C₁-C₅ alkyl. In still other specific embodiments, n has a value of 1, 2, 3 or 4.

The precursors of the disclosure can be supplied in any suitable form for volatilization to produce the precursor vapor for deposition contacting with the substrate, e.g., in a liquid form that is vaporized or as a solid that is dissolved or suspended in a solvent medium for flash vaporization, as a sublimable solid, or as a solid having sufficient vapor pressure to render it suitable for vapor delivery to the deposition chamber, or in any other suitable form.

When solvents are employed for delivery of the precursors of the disclosure, any suitable solvent medium can be employed in which the precursor can be dissolved or dispersed for delivery. By way of example, the solvent medium may be a single-component solvent or a multicomponent solvent mixture, including solvent species such as C₃-C₁₂ alkanes, C₂-C₁₂ ethers, C₆-C₁₂ aromatics, C₇-C₁₆ arylalkanes, C₁₀-C₂₅ arylcyloalkanes, and further alkyl-substituted forms of aromatic, arylalkane and arylcyloalkane species, wherein the further alkyl substituents in the case of multiple alkyl substituents may be the same as or different from one another and wherein each is independently selected from C₁-C₈ alkyl.

Illustrative solvents include amines, ethers, aromatic solvents, glymes, tetraglymes, alkanes, alkyl-substituted benzene compounds, benzocyclohexane (tetralin), alkyl-substituted benzocyclohexane and ethers, with tetrahydrofuran, xylene, 1,4-tertbutyltoluene, 1,3-diisopropylbenzene, dimethyltetralin, octane and decane being potentially useful solvent species in specific applications.

In some embodiments, it may be desirable to utilize aromatic solvents such as xylene, 1,4-tertbutyltoluene, 1,3-diisopropylbenzene, tetralin, dimethyltetralin and other alkyl-substituted aromatic solvents. The solvent medium may also comprise a stabilizing solvent, e.g., a Lewis-base ligand.

In other embodiments, preferred solvents may include amine solvents, neutral amines such as DMAPA, octane or other aliphatic solvents, aromatic solvents such as toluene, ethers such as tetrahydrofuran (THF), and tetraglymes.

In specific applications, the precursors may be supplied in liquid delivery systems as individual precursors or mixtures of precursors, in solvent media that may be comprised of a single component solvent, or alternatively may be constituted by a solvent mixture, as appropriate in a given application. The solvents that may be employed for such purpose can be of any suitable type in which the specific precursor(s) can be dissolved or suspended, and subsequently volatilized to form the precursor vapor for contacting with the substrate on which the zirconium metal is to be deposited.

The disclosure also contemplates delivery of the precursor by bubbler delivery techniques, in which the bubbler is arranged to operate at or above the melting point of the precursor.

In general, the precursor compositions may alternatively comprise, consist, or consist essentially of any of the components and functional moieties disclosed herein, in specific embodiments of the disclosure.

Precursors of the disclosure can be utilized in combinations, in which two or more of such precursors are mixed with one another, e.g., in a solution as a precursor cocktail composition for liquid delivery.

In some embodiments, the precursor species are individually dissolved in solvent(s) and delivered into vaporizers for volatilization of the precursor solution to form a precursor vapor that then is transported to the deposition chamber of the deposition system to deposit the metal-containing film on a wafer or other microelectronic device substrate. In one embodiment, the precursor is dissolved in an ionic liquid medium, from which precursor vapor is withdrawn from the ionic liquid solution under dispensing conditions.

In other embodiments, the precursors are delivered by solid delivery techniques, in which the solid is volatilized to form the precursor vapor that then is transported to the deposition chamber, and with the solid precursor in the first instance being supplied in a packaged form for use.

As a still further alternative, the precursor may be stored in an adsorbed state on a suitable solid-phase physical adsorbent storage medium in the interior volume of the vessel. In use, the precursor vapor is dispensed from the vessel under dispensing conditions involving desorption of the adsorbed precursor from the solid-phase physical adsorbent storage medium.

In general, supply vessels for precursor delivery may be of widely varying type, and may employ vessels such as those commercially available from ATMI, Inc. (Danbury, Conn., USA) under the trademarks SDS, SAGE, VAC, VACSorb, and ProE-Vap, as may be appropriate in a given storage and dispensing application for a particular precursor of the present disclosure.

The precursors of the disclosure thus may be employed to form precursor vapor for contacting with a substrate to deposit metal-containing thin films thereon.

In a preferred aspect, the precursors of the disclosure can be employed to conduct atomic layer deposition, yielding ALD films of superior conformality that are uniformly coated on the substrate with high step coverage and conformality even on high aspect ratio structures.

Accordingly, the precursors of the present invention enable a wide variety of microelectronic devices, e.g., semiconductor products, flat panel displays, etc., to be fabricated with zirconium-containing films of superior quality.

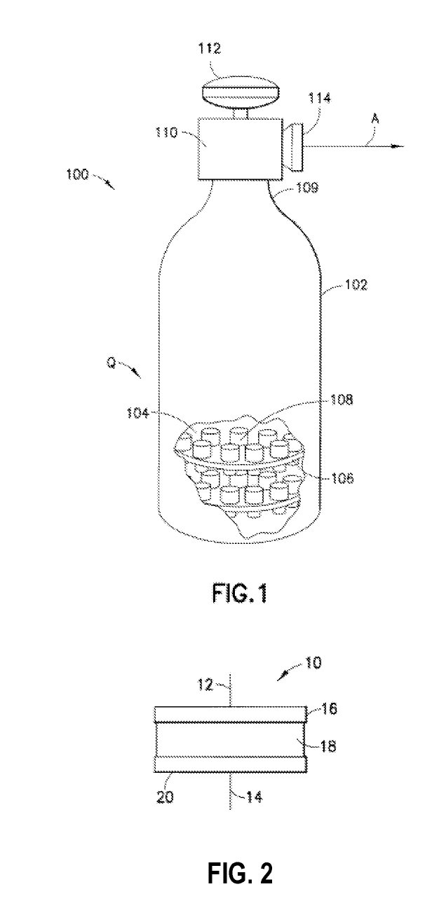

FIG. 1 is a schematic representation of a microelectronic device structure comprising a capacitor 10, including a zirconium dioxide-based dielectric material 18 between a top electrode 16 associated with lead 12, and bottom electrode 20 associated with lead 14. The dielectric material 18 may be formed by ALD using a zirconium precursor of the present invention to deposit the zirconium-based dielectric material on the bottom electrode, prior to formation of the top electrode layer.

FIG. 2 is a schematic representation of a material storage and dispensing package 100 containing a metal precursor, according to one embodiment of the present invention.

The material storage and dispensing package 100 includes a vessel 102 that may for example be of generally cylindrical shape as illustrated, defining an interior volume 104 therein. In this specific embodiment, the precursor is a solid at ambient temperature conditions, and such precursor may be supported on surfaces of the trays 106 disposed in the interior volume 104 of the vessel, with the trays having flow passage conduits 108 associated therewith, for flow of vapor upwardly in the vessel to the valve head assembly for dispensing, in use of the vessel.

The solid precursor can be coated on interior surfaces in the interior volume of the vessel, e.g., on the surfaces of the trays 106 and conduits 108. Such coating may be effected by introduction of the precursor into the vessel in a vapor form from which the solid precursor is condensed in a film on the surfaces in the vessel. Alternatively, the precursor solid may be dissolved or suspended in a solvent medium and deposited on surfaces in the interior volume of the vessel by solvent evaporation. In yet another method the precursor may be melted and poured onto the surfaces in the interior volume of the vessel. For such purpose, the vessel may contain substrate articles or elements that provide additional surface area in the vessel for support of the precursor film thereon.

As a still further alternative, the solid precursor may be provided in granular or finely divided form, which is poured into the vessel to be retained on the top supporting surfaces of the respective trays 106 therein. As a further alternative, a metal foam body may be provided in the interior volume of the vessel, which contains porosity of a specific character adapted for retaining the solid particulate precursor for highly efficient vaporization thereof.

The vessel 102 has a neck portion 109 to which is joined the valve head assembly 110. The valve head assembly is equipped with a hand wheel 112 in the embodiment shown. In lieu of a hand wheel, the valve head assembly may in turn be coupled or operatively linked to a controller for automated operation. The valve head assembly 110 includes a dispensing port 114, which may be configured for coupling to a fitting or connection element to join flow circuitry to the vessel. Such flow circuitry is schematically represented by arrow A in FIG. 2, and the flow circuitry may be coupled to a downstream ALD or chemical vapor deposition chamber (not shown in FIG. 2).

In use, the vessel 102 can be heated with a suitable heater, such as a heating jacket, resistance heating elements affixed to the exterior wall surface of the vessel, etc., so that solid precursor in the vessel is at least partially volatilized to provide precursor vapor. The input of heat is schematically shown in FIG. 2 by the reference arrow Q. The precursor vapor is discharged from the vessel through the valve passages in the valve head assembly 110 when the hand wheel 112 or alternative valve actuator or controller is translated so that the valve is in an open position, whereupon vapor deriving from the precursor is dispensed into the flow circuitry schematically indicated by arrow A.

While the invention has been has been described herein in reference to specific aspects, features and illustrative embodiments of the invention, it will be appreciated that the utility of the invention is not thus limited, but rather extends to and encompasses numerous other variations, modifications and alternative embodiments; as will suggest themselves to those of ordinary skill in the field of the present invention, based on the disclosure herein. Correspondingly, the invention as hereinafter claimed is intended to be broadly construed and interpreted, as including all such variations, modifications and alternative embodiments, within its spirit and scope.

What is claimed is:

1. A precursor selected from the group consisting of compounds of Formulae (I), (II) and (III): 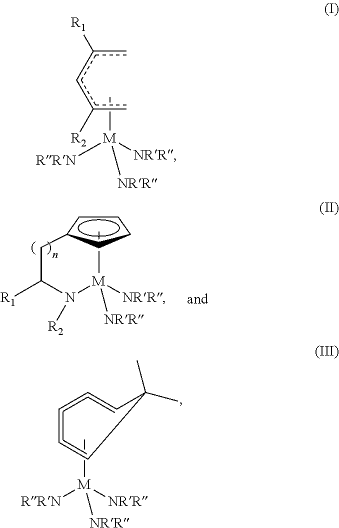
wherein:
M is Zr, Hf or Ti;
R₁ is hydrogen or C₁-C₅ alkyl;
each of R₂, R′ and R″ is independently selected from C₁-C₅ alkyl; and
n has a value of 0, 1, 2, 3 or 4.

2. The precursor of claim 1, comprising a zirconium precursor of Formula (I).

3. The precursor of claim 1, comprising a zirconium precursor of Formula (II).

4. The precursor of claim 1, comprising a zirconium precursor of Formula (III).

5. The precursor of claim 1, comprising a hafnium precursor of Formula (I).

6. The precursor of claim 1, comprising a hafnium precursor of Formula (II).

7. The precursor of claim 1, comprising a hafnium precursor of Formula (III).

8. The precursor of claim 1, comprising a titanium precursor of Formula (I).

9. The precursor of claim 1, comprising a titanium precursor of Formula (II).

10. The precursor of claim 1, comprising a titanium precursor of Formula (III).

11. A precursor composition, comprising a precursor of claim 1, and a solvent medium therefor.

12. The precursor composition of claim 14, wherein the solvent medium comprises at least one solvent selected from the group consisting of: C₃-C₁₂ alkanes, C₂-C₁₂ ethers, C₆-C₁₂ aromatics, C₇-C₁₆ arylalkanes, C₁₀-C₂₅ arylcyloalkanes, and further alkyl-substituted forms of aromatic, arylalkane and arylcyloalkane species, wherein the further alkyl substituents in the case of multiple alkyl substituents may be the same as or different from one another and wherein each is independently selected from C₁-C₈ alkyl, amines, ethers, aromatic solvents, glymes, tetraglymes, alkanes, alkyl-substituted benzene compounds, benzocyclohexane (tetralin), alkyl-substituted benzocyclohexane and ethers, tetrahydrofuran, xylene, 1,4-tertbutyltoluene, 1,3-diisopropylbenzene, dimethyltetralin, octane, decane, alkyl-substituted aromatic solvents, and stabilizing solvents including Lewis-base ligands.

13. A method of forming a film on a substrate, comprising conducting a vapor deposition process using a precursor of claim 1 as a metal source compound for said vapor deposition process.

14. A precursor supply package, comprising a vessel, and a precursor of claim 1 contained in the vessel, wherein the vessel is adapted for storage and dispensing of said precursor.

15. A precursor composition, comprising a precursor of claim 1, and a vapor deposition stabilization additive comprising a stabilizer selected from the group consisting of: alkylamines; free radical inhibitors; and compounds that maintain precursor metal in a +4 oxidation state.

16. A zirconium precursor selected from the group consisting of compounds of Formulae (I) and (II): 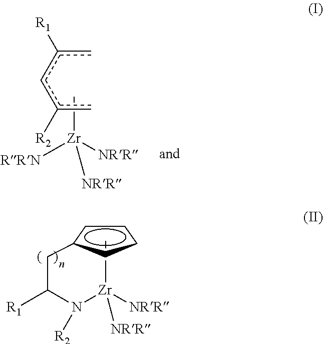
wherein:
R₁ is hydrogen or C₁-C₅ alkyl;
each of R₂, R′ and R″ is independently selected from C₁-C₅ alkyl; and
n has a value of 0, 1, 2, 3 or 4.

17. The zirconium precursor of claim 16, selected from the group consisting of compounds of Formula (I), wherein R₁ is hydrogen, and R₁ is C₁-C₅ alkyl.

18. The zirconium precursor of claim 16, selected the group consisting of compounds of Formula (II), wherein R₁ is hydrogen, R₁ is C₁-C₅ alkyl, and n has a value of 1, 2, 3, or 4.

19. A method of forming a zirconium-containing film on a substrate, comprising conducting an atomic layer deposition process using a zirconium precursor of claim 16 as a metal source compound for said atomic layer deposition process.

20. The method of claim 19, wherein the zirconium-containing film is part of a DRAM device.

21. A vessel containing a zirconium precursor of claim 16.

22. A composition comprising a compound of claim 16 and a vapor deposition stabilization additive comprising at least one stabilizer selected from the group consisting of: alkylamines; free radical inhibitors; and compounds that maintain Zr in a +4 oxidation state.
